(19) United States
(12) Patent Application Publication
(10) Pub. No.: US 2004/0207088 A1
(43) Pub. Date: Oct. 21, 2004

(54) Semiconductor device and method for manufacturing the same

(75) Inventor: Yukio Morozumi, Chino-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/788,331

(22) Filed: Mar. 1, 2004

(30) Foreign Application Priority Data
Mar. 6, 2003 (JP) 2003-059453

(51) Int. Cl. H01L 23/48

(52) U.S. Cl. 257/758

(57) ABSTRACT

[Object]

To provide semiconductor devices in which rewirings can be readily processed finely and accurately, and methods for manufacturing the same.

[Means for Solution]

A method for manufacturing a semiconductor device in accordance with the present invention is equipped with a step of forming wirings 9a, 9b on a semiconductor substrate 1; a step of forming a passivation film 10 over the wirings; a step of forming a first dielectric film 11 over the passivation film; a step of forming a groove for rewiring in the first dielectric film; a step of forming a conductive layer in the groove for rewiring and on the first dielectric film; and a step of forming a rewiring 15 composed of the conductive layer embedded in the groove for rewiring and the connection hole by polishing/removing the conductive layer that is present on the first dielectric film by CMP.

### DETAILED DESCRIPTION OF THE INVENTION

1. Technical Field of the Invention

The present invention relates to semiconductor devices and methods for manufacturing the same, and more particularly, to semiconductor devices and methods for manufacturing the same relating to wafer-level CSP (chip size package).

2. Conventional Art

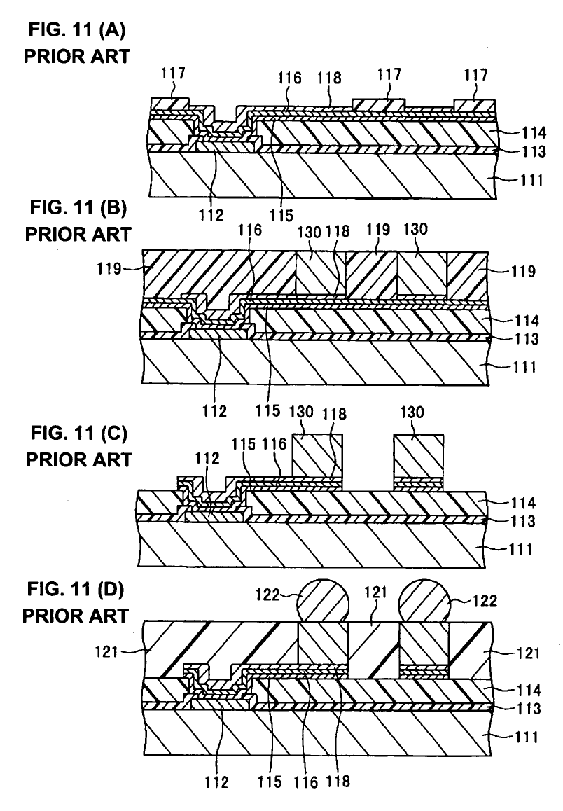

FIGS. 11(A)-(D) are cross-sectional views indicating a conventional method for manufacturing a semiconductor device. The semiconductor device is a wafer-level CSP.

First, as indicated in FIG. 11(A), after an opening is formed in a protection dielectric layer 113 such as a silicon nitride film and a polyimide layer 114 disposed over an Al alloy wiring pad 112 on a silicon substrate 111 having semiconductor elements formed therein, a seed layer 116 is formed on an adhesion layer 115 such as Cr or TiW by sputtering Cu thereon, and the Cu is selectively plated by using a resist 117 to form a rewiring layer 118 for a leading out purpose.

Next, as indicated in FIG. 11(B), the thick Cu layer and a barrier layer (not shown) are selectively plated by using another resist 119 as a mask, to form Cu posts 130 having the barrier layers stacked in layers.

Next, as indicated in FIG. 11(C), after the resist 119 is separated, the seed layer 116 and the adhesion layer 115 are etched and removed by using the rewiring layer 118 as a mask, such that wirings separated from one another are formed.

Further, as indicated in FIG. 11(D), at least a top surface among the entire surface of the silicon substrate 111 is sealed with sealing resin 121, and then the resin 121 is ground or mechanically polished to expose the barrier layers on the surface of the Cu posts 130. Further, solder balls are mounted on regions of the respective posts 130 by an automatic transferring and mounting apparatus, and a heat treatment is conducted to weld the solder balls to the posts, to thereby form external terminals 122. Thereafter, the electric property is examined, and dicing is conducted to provide individual chips, which are mounted on motherboards or the like of portable devices.

[Patent Document 1]

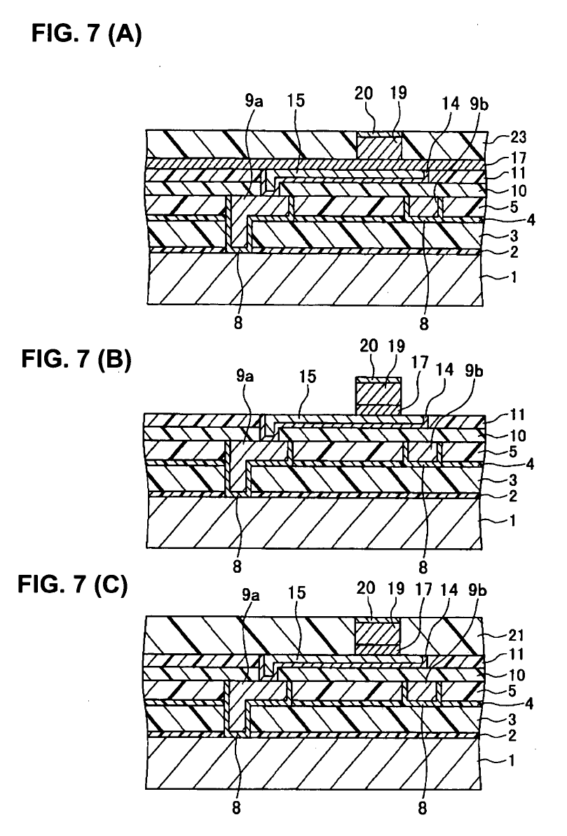

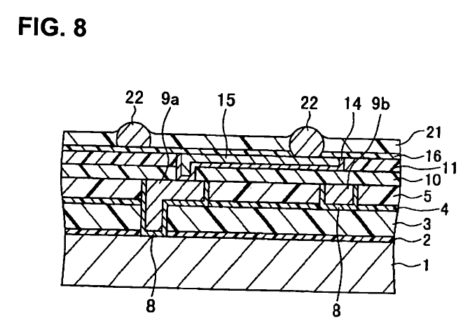

Japanese Laid-open Patent Application 2001-244372 (Pages 2-3, FIG. 7, FIG. 8)

[Problems to be Solved by the Invention]

In the conventional method for manufacturing a semiconductor device described above, the adhesion layer 115 and the seed layer 116 are formed by sputtering, and the rewiring layer 118 is formed by selective plating. For this reason, it is relatively difficult to finely and precisely process rewiring layers. Accordingly, the yield at the time of manufacturing would likely lower, and it would not be easy to increase the number of external terminals.

The present invention has been made in view of the circumstances described above, and its object is to provide semiconductor devices in which fine and precise rewirings can be readily processed, and to provided methods for manufacturing the same.

[Means to Solve the Problems]

To solve the problems described above, a method for manufacturing a semiconductor device in accordance with the present invention is equipped with:

a step of forming a wiring on a semiconductor substrate;

a step of forming a passivation film over the wiring;

a step of forming a first dielectric film over the passivation film;

a step of forming a groove for rewiring in the first dielectric film;

a step of forming a conductive layer in the groove for rewiring and on the first dielectric film; and

a step of forming a rewiring composed of the conductive layer embedded in the groove for rewiring and the connection hole by polishing/removing the conductive layer that is present on the first dielectric film by CMP.

According to the method for manufacturing a semiconductor device described above, the first dielectric film is formed over the passivation film, the groove for rewiring is formed in the first dielectric film, and the rewiring is formed in the groove for rewiring. Accordingly, fine and precise processing of rewirings becomes easy.

Also, the method for manufacturing a semiconductor device in accordance with the present invention can further be equipped with, after the step of forming the rewiring, a step of forming a second dielectric film over the rewiring and the first dielectric film, a step of forming an opening section in the second dielectric film at a location above the rewiring, and a step of forming a metal post in the opening section and on the second dielectric film.

Also, the method for manufacturing a semiconductor device in accordance with the present invention can further be equipped with, after the step of forming the rewiring, a step of forming a metal post on the rewiring by an electroplating method or an electroless plating method.

Also, the method for manufacturing a semiconductor device in accordance with the present invention can further be equipped with, after the step of forming the rewiring, a step of forming resin to cover a side surface of the metal post and the rewiring.

Also, the method for manufacturing a semiconductor device in accordance with the present invention can further be equipped with, after the step of forming the resin, a step of disposing an external terminal on the metal post.

Also, the method for manufacturing a semiconductor device in accordance with the present invention can further be equipped with, after the step of forming the rewiring, a step of disposing an external terminal on the rewiring.

A method for manufacturing a semiconductor device in accordance with the present invention is equipped with:

a step of forming a wiring on a semiconductor substrate;

a step of forming a passivation film over the wiring;

a step of forming a dielectric film over the passivation film;

a step of forming a groove for rewiring in the dielectric film;

a step of forming a conductive layer in the groove for rewiring and on the dielectric film;

a step of forming a rewiring composed of the conductive layer embedded in the groove for rewiring by polishing/removing the conductive layer that is present on the dielectric film by CMP;

a step of forming an etching protection film over the rewiring and the dielectric film;

a step of forming an opening section in the etching protection film at a location above the rewiring;

a step of forming an adhesion layer in the opening section and on the etching protection film;

a step of forming a metal post on the adhesion layer;

a step of forming a sidewall on a side wall of the metal post; and

a step of etching the adhesion layer by using the sidewall and the metal post as a mask.

According to the method for manufacturing a semiconductor device described above, since the rewiring is formed in the groove for rewiring, fine and precise processing of rewirings becomes easy. Further, because the sidewall is formed on the side wall of the metal post, the metal post is protected by the sidewall from etching damage and corrosion when the adhesion layer is etched by using the metal post as a mask.

Also, according to the method for manufacturing a semiconductor device in accordance with the present invention, the adhesion layer may preferably be a layer composed of high melting point metal, an alloy of high melting point metal or a nitride of high melting point metal, and the etching protection film may preferably be a silicon nitride film.

A semiconductor device in accordance with the present invention is equipped with:

a wiring formed on a semiconductor substrate;

a passivation film formed over the wiring;

a first dielectric film formed over the passivation film;

a groove for rewiring formed in the first dielectric film and the passivation film; and

a rewiring embedded in the groove for rewiring.

Also, the semiconductor device in accordance with the present invention can further be equipped with a second dielectric film formed over the rewiring and the first dielectric film, an opening section formed in the second dielectric film and located above the rewiring, and a metal post formed in the opening section and on the second dielectric film.

Also, in the semiconductor device in accordance with the present invention, at least one of the first dielectric film and the second dielectric film may preferably be a film composed of polyimide.

Also, the semiconductor device in accordance with the present invention can further be equipped with a metal post formed on the rewiring.

Also, the semiconductor device in accordance with the present invention can further be equipped with an external terminal disposed on the metal post.

A semiconductor device in accordance with the present invention is equipped with:

a wiring formed on a semiconductor substrate;

a passivation film formed over the wiring;

a first dielectric film formed over the passivation film;

a groove for rewiring formed in the first dielectric film and the passivation film;

a rewiring embedded in the groove for rewiring; and

an external terminal disposed on the rewiring.

A semiconductor device in accordance with the present invention is equipped with:

a wiring formed on a semiconductor substrate;

a passivation film formed over the wiring;

a dielectric film formed over the passivation film;

a groove for rewiring formed in the dielectric film;

a rewiring embedded in the groove for rewiring;

an etching protection film formed over the rewiring and the dielectric film;

an opening section formed in the etching protection film and located above the rewiring;

an adhesion layer formed in the opening section and on the etching protection film;

a metal post formed on the adhesion layer; and

a sidewall formed on a side wall of the metal post.

[Embodiments of the Invention]

Embodiments of the present invention will be described below with reference to the accompanying drawings.

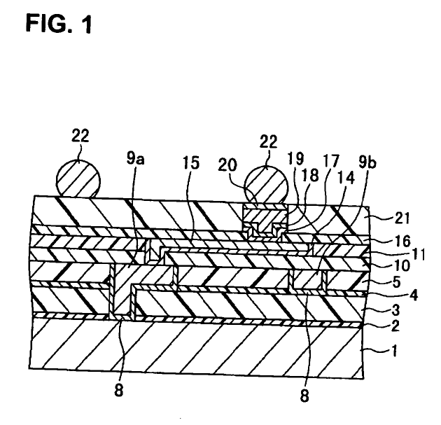

FIG. 1 is a cross-sectional view of a semiconductor device in accordance with a first embodiment of the present invention. The semiconductor device illustrated is a wafer-level CSP, and is in the state of a semiconductor wafer before being cut into chips in a dicing process.

As shown in FIG. 1, a first etching stopper film 2 composed of a silicon nitride film is formed on an active surface of a semiconductor wafer (semiconductor substrate) 1 in which semiconductor elements and wirings (not shown) are formed. A first interlayer dielectric film 3 composed of a silicon oxide film is formed on the first etching stopper film 2, and a second etching stopper film 4 composed of a silicon nitride film is formed on the first interlayer dielectric film 3. A second interlayer dielectric film 5 composed of a silicon oxide film or a Low k material film (a low dielectric constant material film) is formed on the second etching stopper film 4.

A Cu wiring 9a is formed by a damascene method in the first and second interlayer dielectric films 3 and 5 and the first and second etching stopper films 2 and 4, and a Cu wiring 9b is formed by a damascene method in the second interlayer dielectric film 5 and the second etching stopper film 4. Adhesion layers 8 are formed on bottom and side surfaces of the Cu wirings 9a and 9b. A last protection dielectric layer (a passivation film) 10 is formed on the Cu wirings 9a and 9b and the second interlayer dielectric film 5. A first dielectric film 11 composed of a silicon oxide film or a Low k material film is formed on the last protection dielectric layer 10.

A rewiring 15 composed of Cu is formed by a damascene method in the first dielectric film 11 and the last protection dielectric layer 10, and an adhesion layer 14 composed of a high melting point metal is formed on bottom and side surfaces of the rewiring 15. A second dielectric film 16 composed of a silicon oxide film or a silicon nitride film is formed on the rewiring 15 and the first dielectric film 11.

An opening section is formed in the second dielectric film 16 at a position above the rewiring 15, and an adhesion layer 17 composed of a high melting point metal such as Ti, Ta, W or the like, or an alloy or a nitride film of the aforementioned metal is formed in the opening section and on the second dielectric film 16. A Cu seed layer 18 is formed on the adhesion layer 17, and a metal post 19 composed of a Cu layer is formed on the Cu seed layer 18. A cap of dissimilar metal 20 composed of Ni or Au is formed on the metal post 19 by a plating method.

Sealing resin 21 such as epoxy resin or the like is formed on the side surface of the metal post 19 and on the second dielectric film 16, and an upper surface of the metal post 19 is exposed through the sealing resin 21.

External terminals for mounting 22 such as solder balls are formed on the exposed upper surfaces of the metal posts 19 depending on the requirements.

It is noted that the external terminals for mounting 22 are not necessarily required, and a semiconductor device can be manufactured without providing external terminals for mounting formed thereon.

Next, a method for manufacturing the semiconductor device shown in FIG. 1 will be described.

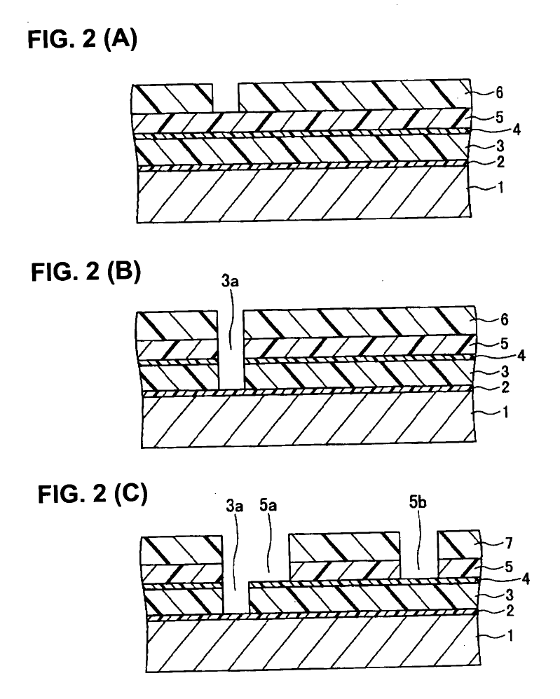

FIGS. 2-5 are cross-sectional views indicating a method for manufacturing the semiconductor device shown in FIG. 1.

First, as shown in FIG. 2(A), a semiconductor substrate (semiconductor wafer) 1 is prepared. Semiconductor elements such as MOS transistors, various metal wirings electrically connected thereto, interlayer dielectric films and the like are formed within the semiconductor substrate 1.

Next, a first etching stopper film 2 composed of, for example, a silicon nitride film is formed on the semiconductor substrate 1 by a CVD (Chemical Vapor Deposition) method. Then, a first interlayer dielectric film 3 composed of a silicon oxide film is deposited on the first etching stopper film 2 by a CVD method, and a second etching stopper film 4 composed of a silicon nitride film is formed on the first interlayer dielectric film 3 by a CVD method. Then, a second interlayer dielectric film 5 composed of a silicon oxide film is deposited on the second etching stopper film 4. Next, a photoresist film is coated on the second interlayer dielectric film 5; and by exposing and developing the photoresist film, a resist pattern 6 having an opening section as a connection aperture is formed on the second interlayer dielectric film 5.

Next, as shown in FIG. 2(B), the second interlayer dielectric film 5, the second etching stopper film 4 and the first interlayer dielectric film 3 are etched by using the resist pattern 6 as a mask. As a result, a via hole (connection hole) 3a is formed in the first and second interlayer dielectric films 3 and 5 and the etching stopper film 4.

Then, as shown in FIG. 2(C), after the resist pattern 6 has been removed, a photoresist film is coated on the second interlayer dielectric film 5, and the photoresist film is exposed and developed. By this, a resist pattern 7 having opening sections for forming grooves for wiring is provided on the second interlayer dielectric film 5. Next, the second interlayer dielectric film 5 is etched using the resist pattern 7 as a mask and the first and second etching stopper films 2 and 4 as stoppers. By this, grooves for wiring 5a and 5b are formed in the second interlayer dielectric film 5, and the groove for wiring 5a connects to the via hole 3a.

Next, the first and second etching stopper films 2 and 4 have been etched by using the resist pattern 7 as a mask, and then the resist pattern 7 is removed.

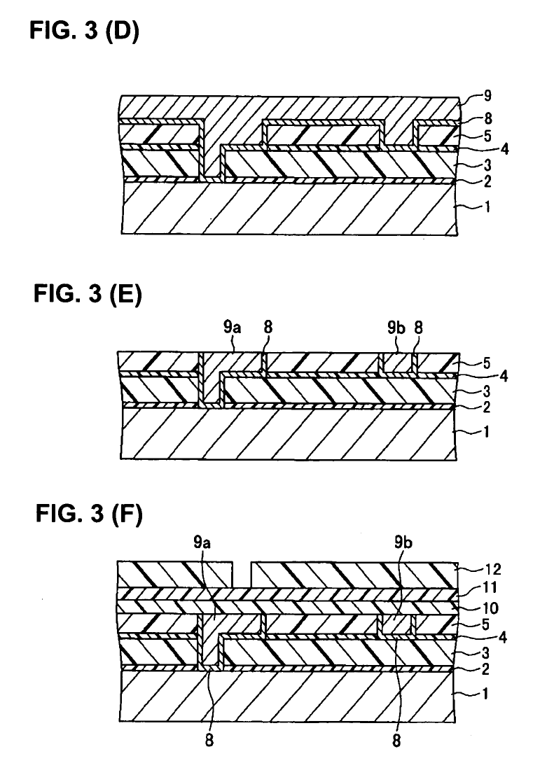

Then, as shown in FIG. 3(D), an adhesion layer (barrier layer) 8 composed of TaN, TiW or TiN is formed by sputtering in the via hole 3a and the grooves for wiring 5a and 5b and on the second interlayer dielectric film 5. Then, a Cu seed layer (not shown) for electroplating is formed by sputtering on the adhesion layer 8. Next, a Cu layer 9 is formed by an electroplating method on the Cu seed layer in the grooves for wiring 5a and 5b and in the connection hole 3a.

Then, as shown in FIG. 3(E), the Cu layer 9, the Cu seed layer and the adhesion layer 8 that are present on the second interlayer dielectric film 5 are polished and removed by a CMP (chemical mechanical polishing) method. By this, the Cu layer 9 is embedded in the via hole 3a in the first interlayer dielectric film 3 and in the grooves for wiring 5a and 5b in the second interlayer dielectric film 5. In other words, Cu wirings 9a and 9b are formed in the grooves for wiring 5a and 5b, and the Cu wiring 9a is electrically connected to a wiring in a lower layer (not shown) through the Cu layer embedded in the via hole 3a.

Next, as shown in FIG. 3(F), a last protection dielectric layer (passivation film) 10 composed of a silicon nitride film is formed by a plasma CVD method on the entire surface including those of the Cu wirings 9a and 9b. Next, a first dielectric film 11 composed of a silicon oxide film is formed by a CVD method on the last protection dielectric layer 10. Then, a photoresist film is coated on the first dielectric film 11, and the photoresist film is exposed and developed to thereby form a resist pattern 12 on the first dielectric film 11.

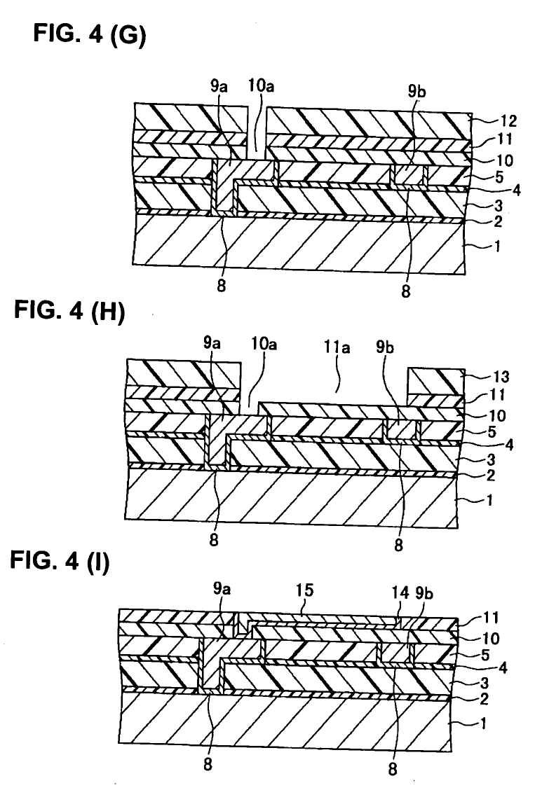

Then, as shown in FIG. 4(G), the first dielectric film 11 and the last protection dielectric layer 10 are etched by using the resist pattern 12 as a mask, thereby forming a via hole (connection hole) 10a in the first dielectric film 11 and the last protection dielectric layer 10.

Next, as shown in FIG. 4(H), after the resist pattern 12 has been removed, a photoresist film is coated on the first dielectric film 11, and the photoresist film is exposed and developed. By this, a resist pattern 13 having an opening section for forming a groove for rewiring is provided on the first dielectric film 11. Next, the first dielectric film 11 is etched by using the resist pattern 13 as a mask and the last protection dielectric layer 10 as an etching stopper. By this, a groove for rewiring 11a is formed in the first dielectric film 11, and the groove for rewiring 11a connects to the via hole 10a.

Then, as shown in FIG. 4(I), after the resist pattern 13 has been removed, an adhesion layer 14 composed of a high melting point metal is formed by sputtering in the via hole 10a, in the groove for rewiring 11a and on the first dielectric film 11. Next, a Cu seed layer (not shown) is formed by sputtering on the adhesion layer 14. Then, a Cu layer is formed by an electroplating method on the Cu seed layer. Next, the Cu layer and the adhesion layer 14 that are present on the first dielectric film 11 are polished and removed by CMP such that a rewiring 15 is embedded in the groove for rewiring 11a, and the rewiring 15 is electrically connected to the Cu wiring 9a through the Cu layer that is embedded in the via hole 10a.

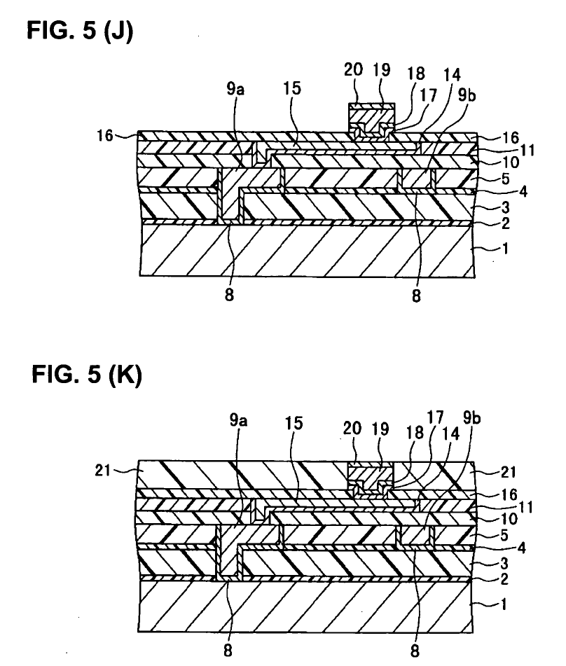

Next, as shown in FIG. 5(J), a second dielectric film 16 composed of a silicon oxide film is formed by a CVD method on the entire surface including the rewiring 15. Then, a photoresist film (not shown) is coated on the second dielectric film 16, and the photoresist film is exposed and developed, thereby forming a resist pattern on the second dielectric film 16.

Then, the second dielectric film 16 is etched by using the resist pattern as a mask, such that an opening section is formed in the second dielectric film 16 at a position above the rewiring 15.

Then, an adhesion layer 17 composed of high melting point metal such as Ti, Ta, W or the like, or an alloy or a nitride film of the aforementioned metal is formed by sputtering in the opening section and on the second dielectric film 16. Next, a photoresist film (not shown) is coated on the adhesion layer 17, and the photoresist film is exposed and developed such that a resist pattern having an opening at a post region is formed on the adhesion layer 17. Then, a Cu seed layer 18 is formed on the adhesion layer 17 in the opening section by a plating method, using the resist pattern as a mask. Then, the resist pattern is removed.

Thereafter, a photoresist film (not shown) is coated on or a photo film (not shown) is adhered to the Cu seed layer 18 and the adhesion layer 17, and the film is exposed and developed, such that a resist pattern having an opening at a post region is formed on the Cu seed layer 18. Then, a Cu layer is formed to a thickness of about several to several ten μm by a selective plating method on the Cu seed layer 18 in the opening, using the resist pattern as a mask. By this, a metal post 19 composed of the Cu layer is formed on the Cu seed layer. It is noted that the thickness and size of the metal post composed of the Cu plated film are relatively easily controlled. Next, a cap 20 of dissimilar metal composed of Ni or Au is formed on the metal post 19 by a plating method. Then, after the resist pattern has been removed, the adhesion layer 17 is etched by using the metal post 19 and the Cu seed layer 18 as a mask.

Next, as shown in FIG. 5(K), sealing resin 21 such as epoxy resin is molded by a molding apparatus, thereby covering the second dielectric film 16 and the metal post 19. Then, the sealing resin 21 is ground by a grinder (not shown) by a desired amount. Here, the desired amount is an amount that exposes the head section (upper section) of the metal post. Next, after flux (not shown) has been coated on exposed portions of the metal posts, solder balls are mounted on designed ones of the metal posts by an automatic mounting apparatus. Then, the metal posts and solder balls are subject to heat treatment at about 170-200° C. By this, the solder balls are fused onto the metal posts 19 as shown in FIG. 1, whereby the external terminals for mounting 22 are formed.

It is noted that solder balls for BGA (Ball Grid Array) that are 150-300 μm in diameter and made from material with Pb/Sn being 60-70 wt % may preferably be used as the solder balls that become the external terminals for mounting. Also, the size of the external terminals for mounting 22 can be appropriately selected. The solder composition can be Ag/Sn material, or Pb-less material including Cu or Bi. Also, the external terminals for mounting are not limited to solder balls. Instead of mounting solder balls, external terminals for mounting that are formed by a printing method, a plating method or a metal jetting method can be used.

Then, through cutting the resin 21 and the semiconductor substrate along scribe lines by using a dicing saw or a laser beam, CSP type semiconductor devices (not shown) can be manufactured. It is noted that a printed circuit board for an electronic device can be listed as one example in which the above-described semiconductor device is mounted. Wirings are patterned on the printed circuit board according to a circuit of the semiconductor device, and the semiconductor device is mounted on each required position of the printed circuit board in a mounting step.

In accordance with the first embodiment described above, the rewiring 15 is formed over the last protection dielectric layer 10 by a damascene method, and the metal posts 19 are formed on the rewiring 15 to provide a wafer level CSP. As the rewiring is formed by a damascene method, the rewiring can be finely and precisely processed, and the rewiring can be prevented from peeling off. Accordingly, occurrence of adhesion failures between long and thin rewirings and their foundation can be suppressed, and occurrence of breakages of adhesion layers and Cu seed layers can be suppressed.

Furthermore, because fine and precise rewirings can be processed, the yield at the time of manufacture can be improved, the manufacturing cost can be lowered, and the number of pins of external terminals can be readily increased. Accordingly, it is effective in display driver ICs of long-side chips with numerous pins.

Also, because fine and precise rewirings can be processed, the chip size can be reduced, such that the size and weight of each package can be reduced.

Also, because fine and precise rewirings can be processed, the reliability of the semiconductor device can be improved. Also, due to the fact that the wiring 15 is covered by the second dielectric film 16 composed of a silicon oxide film or a silicon nitride film, corrosion in a mounting process can be controlled, and the quality and reliability can be improved.

It is noted that the first embodiment can also be modified and implemented in the following manner.

In the present embodiment, the first dielectric film 11 composed of a silicon oxide film is formed on the last protection dielectric layer 10. However, a polyimide layer can be formed on the last protection dielectric layer 10. Also, the polyimide layer acts as a stress relieving layer.

Also, a photosensitive polyimide may preferably be used. By this, photoresist films do not need to be used in the steps indicated in FIG. 3(F), FIG. 4(G) and FIG. 4(H), and therefore the number of steps can be reduced.

Also, in the present embodiment, the second dielectric film 16 composed of a silicon oxide film is formed over the entire surface including the rewiring 15. However, a polyimide layer can be formed over the entire surface including the rewiring 15. In this case, a photosensitive polyimide may preferably be used. By this, a photoresist film does not need to be used in the step of processing the polyimide layer, and therefore the number of steps can be reduced.

Also, in the present embodiment, the Cu wirings 9a and 9b and the rewiring 15 are formed by a damascene method using Cu. However, an Al wiring and Al rewiring can be formed by a damascene method using Al.

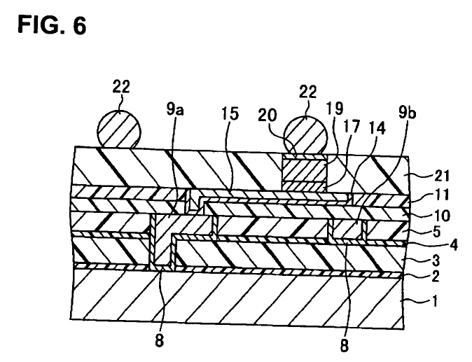

FIG. 6 shows a cross-sectional view of a semiconductor device in accordance with a second embodiment of the present invention, in which the same components as those shown in FIG. 1 are appended with the same codes, and only different portions will be described.

An adhesion layer 17 composed of a high melting point metal such as Ti, Ta, W or the like, or an alloy or a nitride film of the aforementioned metal is formed on a rewiring 15, and a Cu seed layer 18 is formed on the adhesion layer 17. A metal post 19 composed of a Cu layer is formed on the Cu seed layer 18. Sealing resin 21 is formed on side surfaces of the metal post 19, on the rewiring 15 and on the first dielectric film 11.

FIGS. 7(A)-(C) are cross-sectional views indicating a method for manufacturing the semiconductor device shown in FIG. 6, in which the same components as those shown in FIGS. 2-5 are appended with the same codes, and only different portions will be described.

The steps indicated in FIG. 2(A) through FIG. 4(I) of the first embodiment are the same as those in the present embodiment, and therefore their description is omitted.

After the step indicated in FIG. 4(I), an adhesion layer 17 composed of a high melting point metal such as Ti, Ta, W or the like, or an alloy or a nitride film of the aforementioned metal is formed by sputtering on the rewiring 15 and the first dielectric film 11, as shown in FIG. 7(A). Then, a Cu seed layer (not shown) is formed on the adhesion layer 17 by a plating method or a sputtering method.

Then, a photoresist film is coated on or a photo film is adhered to the Cu seed layer and the adhesion layer 17, and the film is exposed and developed, thereby forming a resist pattern 23 having an opening at a post region on the Cu seed layer. Then, a Cu layer is formed to a thickness of about several to several ten μm by a selective plating method on the Cu seed layer in the opening, using the resist pattern 23 as a mask. By this, a metal post 19 composed of the Cu layer is formed on the Cu seed layer. Next, a cap 20 of dissimilar metal composed of Ni or Au is formed on the metal post 19 by a plating method.

Next, as shown in FIG. 7(B), the resist pattern 23 has been removed, and then the adhesion layer 17 and the Cu seed layer are processed by using the metal post 19 as a mask. RIE, wet etching or ion milling can be used as the processing method in this instance. It is noted that, when a polyimide film is used as the first dielectric film, damages including stress can be reduced.

Next, as shown in FIG. 7(C), sealing resin 21 such as epoxy rein is molded by a molding apparatus, thereby covering the metal post 19. Then, the sealing resin 21 is ground by a grinder (not shown) by a desired amount. Here, the desired amount is an amount that exposes the head section (upper section) of the metal post. Next, after flux (not shown) has been coated on exposed portions of the metal posts, solder balls are mounted on designed ones of the metal posts by an automatic mounting apparatus. Then, the metal posts and solder balls are subject to heat treatment at about 170-200° C. By this, the solder balls are fused onto the metal posts 19 shown in FIG. 6, such that the external terminals for mounting 22 are formed.

The second embodiment can provide the same effects obtained by the first embodiment.

Also, since the metal post 19 is formed on the rewiring 15 through the adhesion layer 17, the number of steps can be reduced compared to the first embodiment.

It is noted that the second embodiment can be modified and implemented as follows.

In the present embodiment, the metal post 19 is formed by an electroplating method. However, the metal post 19 can be formed by an electroless plating method. In this case, since the post can be directly formed on the Cu rewiring, a Cu seed layer becomes unnecessary and therefore the number of steps can be reduced, and selective removal of the adhesion layer, which is relatively difficult, becomes unnecessary, and etching damage to the seed layer can be reduced.

FIG. 8 shows a cross-sectional view of a semiconductor device in accordance with a third embodiment of the present invention, in which the same components as those shown in FIG. 1 are appended with the same codes, and only different portions will be described.

External terminals for mounting 22 such as solder balls are disposed in opening sections in a second dielectric film 16 and on the second dielectric film 16. Sealing resin 21 is disposed at bottom sections of the external terminals for mounting 22 and on the second dielectric film.

Next, portions of a method for manufacturing the semiconductor device shown in FIG. 8, which are different from the first embodiment, will be described.

Steps up to the step of forming opening sections in a second dielectric film 16 at positions over a rewiring 15 are the same as those conducted in the first embodiment. Next, flux (not shown) is coated inside the opening sections, solder balls are mounted at the opening sections by an automatic mounting apparatus. Then, the solder balls are subject to heat treatment at about 170-200° C. By this, the solder balls are fused onto the rewiring 15, such that external terminals for mounting 22 are formed.

The third embodiment can provide the same effects as those obtained by the first embodiment.

Also, due to the fact that the external terminals 22 are directly formed on the rewiring 15 inside the opening sections, the number of steps can be reduced compared to the first embodiment.

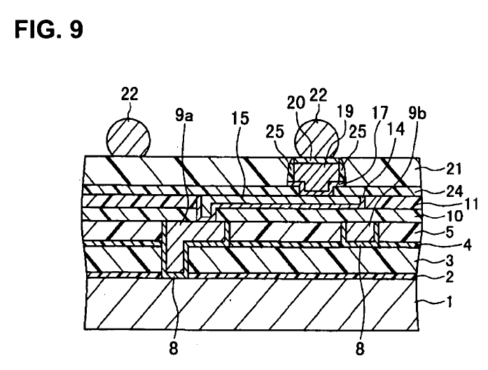

FIG. 9 shows a cross-sectional view of a semiconductor device in accordance with a fourth embodiment of the present invention, in which the same components as those shown in FIG. 1 are appended with the same codes, and only different portions will be described.

A silicon nitride film 24 is formed on a rewiring 15 and a first dielectric film 11. An opening section is formed in the silicon nitride film 24 at a position above the rewiring 15, and an adhesion layer 17 composed of high melting point metal such as Ti, Ta, W or the like, or an alloy or a nitride film of the aforementioned metal is formed in the opening section and on the silicon nitride film 24.

A metal post 19 composed of a Cu layer is formed on the adhesion layer 17. Sidewalls 25 are formed on side walls of a cap of dissimilar metal 20 and the metal post 19 and on the adhesion layer 17. Sealing resin 21 is formed on side surfaces of the sidewalls 25, on the rewiring 15 and on the first dielectric film 11.

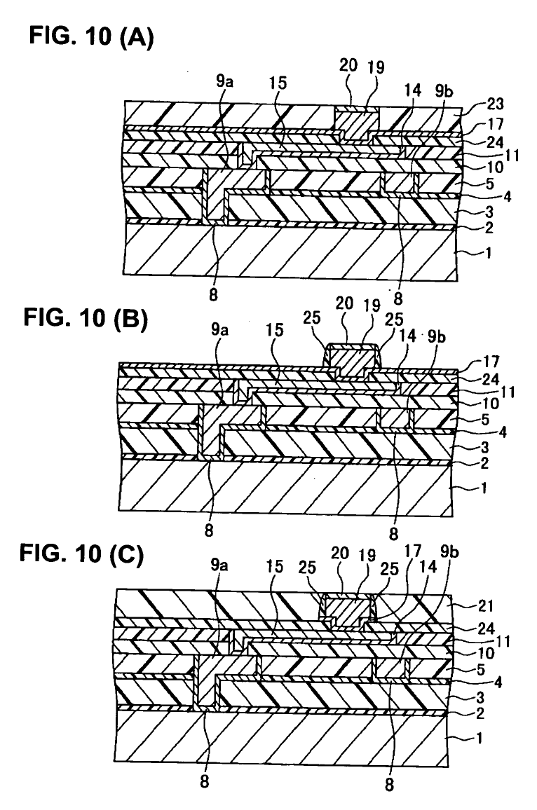

FIGS. 10(A)-(C) are cross-sectional views indicating a method for manufacturing the semiconductor device shown in FIG. 9, in which the same components as those shown in FIGS. 2-5 are appended with the same codes, and only different portions will be described.

The steps indicated in FIG. 2(A) through FIG. 4(I) of the first embodiment are the same as those in the present embodiment, and therefore their description is omitted.

After the step indicated in FIG. 4(I), a silicon nitride film 24 is formed as an etching protection film by a plasma CVD method on a rewiring 15 and a first dielectric film 11, as shown in FIG. 10(A). Then, an opening section is formed in the silicon nitride film 24 at a position above the rewiring 15, and an adhesion layer 17 composed of a high melting point metal such as Ti, Ta, W or the like, or an alloy or a nitride film of the aforementioned metal is formed by sputtering in the opening section and on the silicon nitride film 24.

Then, a photoresist film is coated on or a photo film is adhered to the adhesion layer 17, and the film is exposed and developed, thereby forming a resist pattern 23 having an opening at a post region formed on the adhesion layer 17. Next, a Cu layer is formed to a thickness of about several to several ten μm by a selective plating method on the adhesion layer 17 in the opening, using the resist pattern 23 as a mask. By this, a metal post 19 composed of the Cu layer is formed on the Cu seed layer. Next, a cap 20 of dissimilar metal composed of Ni or Au is formed on the metal post 19 by a plating method.

Next, as shown in FIG. 10(B), after the resist pattern 23 has been removed, a silicon oxide film or a silicon nitride film is deposited by a CVD method over the entire surface including the metal post 19, and the silicon oxide film or the silicon nitride film is etched back, whereby sidewalls 25 composed of silicon oxide films or silicon nitride films are formed on side walls of the metal post 19.

Then, as shown in FIG. 10(C), the adhesion layer 17 is etched by using the sidewalls 25 and the metal post 19 as a mask. It is noted that the etching of the adhesion layer and the etching to form the sidewalls can be successively conducted in the same chamber. Next, sealing resin 21 such as epoxy resin is molded by a molding apparatus, thereby covering the metal post 19. Then, the sealing resin 21 is ground by a grinder (not shown) by a desired amount. Here, the desired amount is an amount that exposes the head section (upper section) of the metal post. Next, after flux (not shown) has been coated on exposed portions of the metal posts, solder balls are mounted on designed ones of the metal posts by an automatic mounting apparatus. Then, the metal posts and solder balls are subject to heat treatment at about 170-200° C. By this, the solder balls are fused onto the metal posts 19 shown in FIG. 9, such that the external terminals for mounting 22 are formed.

The fourth embodiment can also provide the same effects obtained by the first embodiment.

Also, due to the fact that the sidewalls 25 are formed on side walls of the metal post 19, the sidewalls can protect the metal post from etching damage and corrosion, when the adhesion layer 17 is etched by using the metal post as a mask. Accordingly, deteriorations that may be caused by oxide films formed on the metal posts, peeling of the metal posts and generation of corrosion are eliminated, such that the yield at the time of manufacture is improved, and the reliability of semiconductor devices can be improved.

Also, due to the fact that the silicon nitride film 24 is formed on the rewiring 15, the silicon nitride film 24 can protect the rewiring 15 from etching damage and corrosion, when the adhesion layer 17 is etched. Accordingly, deteriorations of the rewirings 15 such as increased resistance of the rewirings are eliminated, such that the yield at the time of manufacture is improved, and the reliability of semiconductor devices can be improved.

It is noted that the present invention is not limited to the first through fourth embodiments, and many modifications can be made and implemented without departing from the range of the subject matter of the present invention.

### BRIEF DESCRIPTION OF THE DRAWINGS

[FIG. 1] Cross-sectional view of a semiconductor device in accordance with a first embodiment of the present invention.

[FIG. 2] Cross-sectional views indicating a method for manufacturing the semiconductor device shown in FIG. 1.

[FIG. 3] Cross-sectional views indicating the method for manufacturing the semiconductor device shown in FIG. 1.

[FIG. 4] Cross-sectional views indicating the method for manufacturing the semiconductor device shown in FIG. 1.

[FIG. 5] Cross-sectional views indicating the method for manufacturing the semiconductor device shown in FIG. 1.

[FIG. 6] Cross-sectional view of a semiconductor device in accordance with a second embodiment of the present invention.

[FIG. 7] Cross-sectional views indicating a method for manufacturing the semiconductor device shown in FIG. 6.

[FIG. 8] Cross-sectional view of a semiconductor device in accordance with a third embodiment of the present invention.

[FIG. 9] Cross-sectional view of a semiconductor device in accordance with a fourth embodiment of the present invention.

[FIG. 10] Cross-sectional views indicating a method for manufacturing the semiconductor device shown in FIG. 9.

[FIG. 11] Cross-sectional views indicating a conventional method for manufacturing a semiconductor device.

Description of Codes

1 . . . Semiconductor wafer (semiconductor substrate), 2 . . . First etching stopper film, 3 . . . First interlayer dielectric film, 3a . . . Via hole (connection hole), 4 . . . Second etching stopper film, 5 . . . Second interlayer dielectric film, 5a, 5b . . . Groove for wiring, 6 . . . Resist pattern, 7 . . . Resist pattern, 8 . . . Adhesion layer, 9 . . . Cu layer, 9a, 9b . . . Cu wiring, 10 . . . Last protection dielectric layer (passivation film), 10a . . . Via hole (connection hole), 11 . . . First dielectric film, 11a . . . Grooves for wiring, 12, 13 . . . Resist pattern, 14 . . . Adhesion layer, 15 . . . Rewiring layer, 16 . . . Second dielectric film, 17 . . . Adhesion layer, 18 . . . Cu seed layer, 19 . . . Metal post, 20 . . . Cap of dissimilar metal, 21 . . . Sealing resin, 22 . . . External terminal for mounting, 23 . . . Resist pattern, 24 . . . Silicon nitride film, 25 . . . Sidewall, 111 . . . Silicon substrate, 112 . . . Al alloy wiring pad, 113 . . . Protection dielectric layer, 114 . . . Polyimide layer, 115 . . . Adhesion layer, 116 . . . Seed layer, 117 . . . Resist, 118 . . . Rewiring layer, 119 . . . Resist, 121 . . . Sealing resin, 122 . . . External terminal, 130 . . . Metal post

1. A method to manufacture a semiconductor device, comprising:
forming a wiring on a semiconductor substrate;
forming a passivation film over the wiring;
forming a first dielectric film over the passivation film;
forming a groove for rewiring in the first dielectric film;
forming a conductive layer in the groove for rewiring and on the first dielectric film; and
forming a rewiring composed of the conductive layer embedded in the groove for rewiring and the connection hole by polishing/removing the conductive layer that is present on the first dielectric film by CMP.

2. The method to manufacture a semiconductor device according to claim 1, further comprising:
after forming the rewiring;
forming a second dielectric film over the rewiring and the first dielectric film;
forming an opening section in the second dielectric film at a location above the rewiring; and
forming a metal post in the opening section and on the second dielectric film.

3. The method to manufacture a semiconductor device according to claim 1, further comprising:
after forming the rewiring, forming a metal post on the rewiring by an electroplating method or an electroless plating method.

4. The method to manufacture a semiconductor device according to claim 2, further comprising:
after forming the rewiring, forming resin to cover a side surface of the metal post and the rewiring.

5. The method to manufacture a semiconductor device according to claim 4, further comprising:
after forming the resin, disposing an external terminal on the metal post.

6. The method to manufacture a semiconductor device according to claim 1, further comprising:
after forming the rewiring, disposing an external terminal on the rewiring.

7. A method to manufacture a semiconductor device, comprising:
forming a wiring on a semiconductor substrate;
forming a passivation film over the wiring;
forming a dielectric film over the passivation film;
forming a groove for rewiring in the dielectric film;
forming a conductive layer in the groove for rewiring and on the dielectric film;
forming a rewiring composed of the conductive layer embedded in the groove for rewiring by polishing/removing the conductive layer that is present on the dielectric film by CMP;
forming an etching protection film over the rewiring and the dielectric film;
forming an opening section in the etching protection film at a location above the rewiring;
forming an adhesion layer in the opening section and on the etching protection film;
forming a metal post on the adhesion layer;
forming a sidewall on a side wall of the metal post; and
etching the adhesion layer by using the sidewall and the metal post as a mask.

8. The method to manufacture a semiconductor device according to claim 7, the adhesion layer being a layer composed of high melting point metal, an alloy of high melting point metal or a nitride of high melting point metal, and the etching protection film being a silicon nitride film.

9. A semiconductor device, comprising:
a wiring formed on a semiconductor substrate;
a passivation film formed over the wiring;
a first dielectric film formed over the passivation film;
a groove for rewiring formed in the first dielectric film and the passivation film; and
a rewiring embedded in the groove for rewiring.

10. The semiconductor device according to claim 9, further comprising:
a second dielectric film formed over the rewiring and the first dielectric film;
an opening section formed in the second dielectric film and located above the rewiring; and
a metal post formed in the opening section and on the second dielectric film.

11. The semiconductor device according to claim 10, at least one of the first dielectric film and the second dielectric film being a film composed of polyimide.

12. The semiconductor device according to claim 9, further comprising:
a metal post formed on the rewiring.

13. The semiconductor device according to claim 10, further comprising:
an external terminal disposed on the metal post.

14. A semiconductor device, comprising:
a wiring formed on a semiconductor substrate;
a passivation film formed over the wiring;
a first dielectric film formed over the passivation film;
a groove for rewiring formed in the first dielectric film and the passivation film;
a rewiring embedded in the groove for rewiring; and
an external terminal disposed on the rewiring.

15. A semiconductor device, comprising:
a wiring formed on a semiconductor substrate;
a passivation film formed over the wiring;
a dielectric film formed over the passivation film;
a groove for rewiring formed in the dielectric film;
a rewiring embedded in the groove for rewiring;
an etching protection film formed over the rewiring and the dielectric film;
an opening section formed in the etching protection film and located above the rewiring;
an adhesion layer formed in the opening section and on the etching protection film;
a metal post formed on the adhesion layer; and
a sidewall formed on a side wall of the metal post.
